(19) United States
(12) Patent Application Publication
(10) Pub. No.: US 2012/0206932 A1
(43) Pub. Date: Aug. 16, 2012

(54) WEAVE UNIT WITH UNIFORM ILLUMINATION AND MANUFACTURING METHOD THEREOF

(75) Inventors: CHI-TSUNG PENG, HSIN-CHU (TW); WEN-TING LO, HSIN-CHU (TW)

(73) Assignee: GDH CO., LTD., HSIN-CHU (TW)

(21) Appl. No.: 13/079,088

(22) Filed: Apr. 4, 2011

(30) Foreign Application Priority Data
Feb. 11, 2011 (TW) 100104634

(51) Int. Cl. F21V 8/00; H05K 13/00

(52) U.S. Cl. 362/551; 29/592.1

(57) ABSTRACT

A weave unit includes a plurality of opaque wires; a plurality of transparent wires alternatively weaved with the opaque wires to form a weave structure, wherein a plurality of interweave points is defined on the crossing portions of the opaque wires and the transparent wires; a lighting module disposed on one side of the transparent wires; wherein the density of the interweave point on each of the transparent wires increases in the direction of being away from the lighting module; thereby, the light of the lighting module transmits inside the transparent wires for generating uniform illumination.

### BACKGROUND OF THE INVENTION

1. Field of the Invention

The present invention relates to a weave unit and a manufacturing method thereof. In particular, the present invention relates to a weave unit with uniform illumination and the manufacturing method thereof.

2. Description of Related Art

Lighting devices, such as light-emitting diodes are commonly used in indication, display, illumination applications. For example, the light-emitting diodes are applied as an indication lights on electronic devices, traffic lights, lamps, road lamps. Now, the lighting devices have been integrally combined with textiles, such as clothes and shoes to increase the product value of the textiles.

One of the traditional methods for combining the lighting devices with textiles is as following. The lighting devices are mounted on a flexible printed circuit board and the flexible printed circuit board with the lighting devices is attached on the textiles. However, the flexibility of the printed circuit board is limited and the printed circuit board cannot be bent or kneaded facultatively. On the other hand, the flexible printed circuit board cannot meet the textile requirements of appearance and comfortableness.

One of the traditional methods for combining the lighting devices with shoes is as following. The shoe(s) has printed circuit board embedded in the shoe heel portion thereof. The printed circuit board is used to mount integral circuit and device. Furthermore, there are batteries and switches on the printed circuit board. The switches are connecting with the batteries to turn on/off the power supply of the batteries. On the other hand, the lighting devices on the shoes are connected to the integral circuit via connecting wires. Therefore, when the switches is turned on, the lighting devices on the shoes can be powered on and then generate lights from the shoes.

However, the traditional textiles with lighting devices has disadvantage that the light generated from the lighting devices has an intensity decay issue. The portion of the textiles has high intensity near the light devices; on the contrary, the portion of the textiles has low intensity away from the light devices. In the other words, the light intensity decays along the transmitting distance, and As a result, the light uniformity cannot meet the requirement of high quality and the illumination performance of the textiles is low. Accordingly, what is needed is a weave unit that overcomes the foregoing disadvantages.

### SUMMARY OF THE INVENTION

The instant disclosure provides a weave unit with uniform illumination and the weave unit of the present invention can perform uniform illumination effect.

The instant disclosure provides a weave unit with uniform illumination. The weave unit includes a plurality of opaque wires; a plurality of transparent wires alternatively weaved with the opaque wires to form a weave structure, wherein a plurality of interweave points is defined on the crossing portions of the opaque wires and the transparent wires; a lighting module disposed on one side of the transparent wires; wherein the density of the interweave point on each of the transparent wires increases in the direction of being away from the lighting module; thereby, the light of the lighting module transmits inside the transparent wires for generating uniform illumination.

The instant disclosure provides a manufacturing method of a weave unit with uniform illumination. The method includes the steps of:

Step 1 is providing a plurality of transparent wires and a lighting module disposed on one side of the transparent wires.

Step 2 is a plurality of opaque wires alternatively weaved with the transparent wires to form a weave structure, wherein a plurality of interweave points is defined on the crossing portions of the opaque wires and the transparent wires, and adjusting the tension of the transparent wires so that the density of the interweave point on each of the transparent wires increases in the direction of being away from the lighting module.

Step 3 is applying the lighting module to emit light to transmit inside the transparent wires for generating uniform illumination.

By controlling the tension of the transparent wires, the position of the cross section of the transparent wire(s) and the opaque wire(s) can be modified; therefore, the density of the interweave points defined on the crossing sections of the opaque wire(s) and the transparent wire(s) are adjusted. The interweave points of high density can reflect the light forward along the transparent wire(s) and the light decay of transmitting distance can be compensated. Accordingly, the variation of the density of interweave points can be applied to solve the non-uniform problem.

For further understanding of the present invention, reference is made to the following detailed description illustrating the embodiments and examples of the present invention. The description is for illustrative purpose only and is not intended to limit the scope of the claim.

### BRIEF DESCRIPTION OF THE DRAWINGS

FIG. 1 shows the weave unit with uniform illumination of the instant disclosure.

FIG. 1A shows the lighting module of the weave unit with uniform illumination of the instant disclosure.

FIG. 2 shows the perspective view of the weave unit with uniform illumination of the instant disclosure.

FIG. 3 shows the manufacturing method of the weave unit with uniform illumination according to the instant disclosure.

### DETAILED DESCRIPTION OF THE PREFERRED EMBODIMENTS

The present invention provides a weave unit with uniform illumination and a manufacturing method thereof. By applying the variation of the density of the interweave point on each transparent wire, the weave unit may provide uniform illumination effect, which is resulted from that the light can be transmitted to longer distance from the lighting module.

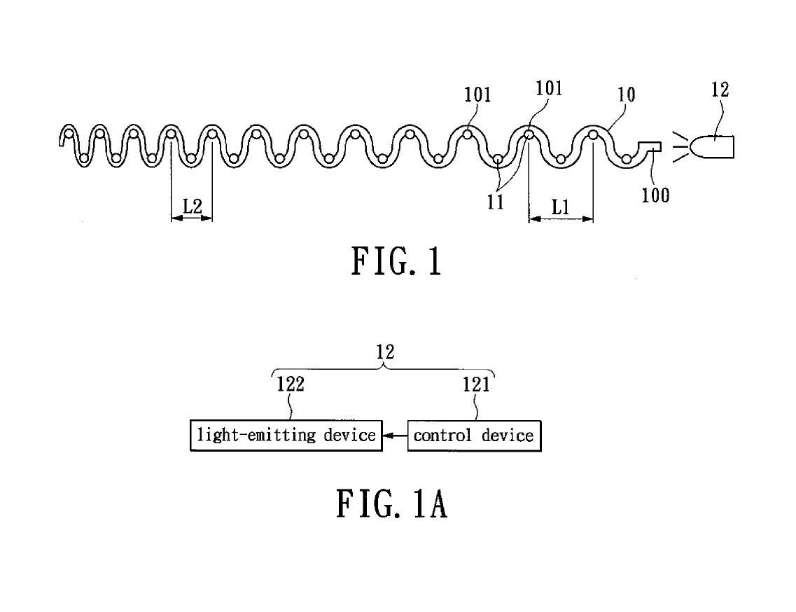

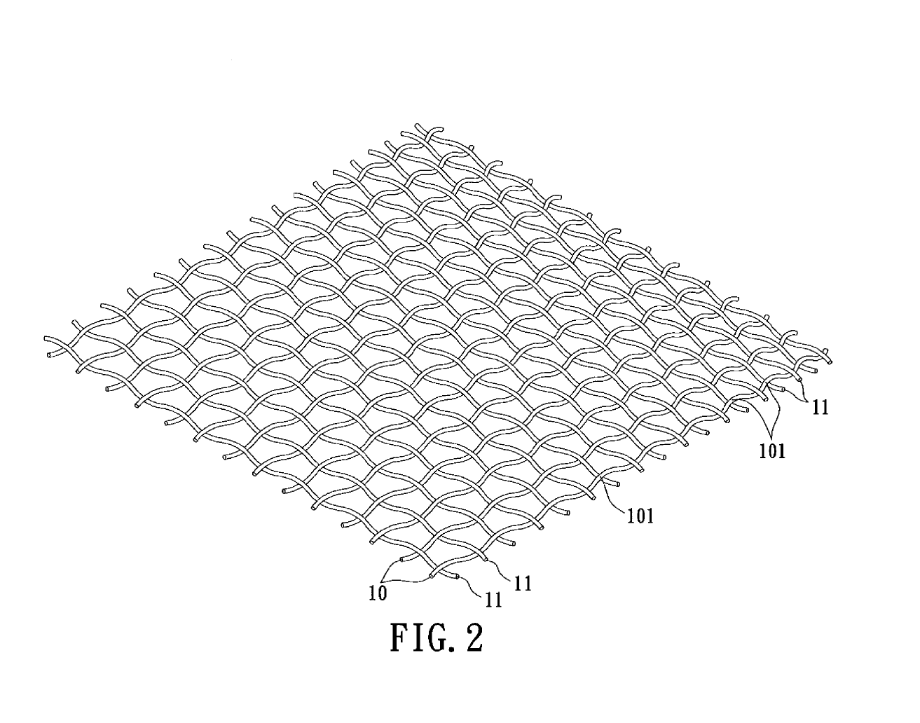

Please refer to FIGS. 1, 1A and 2; the weave unit of the instant disclosure comprises a plurality of opaque wires 11, a plurality of flexible transparent wires 10 and a lighting module 12. In the exemplary embodiment, the opaque wires 11 can be chemical yarns or any non-transparent yarns or fibers. The transparent wires 10 can be optical fibers, fibers with side-lighting function, flexible light-conducting tube or any flexible, transparent wires for transmitting lights. On the other hand, the transparent wires 10 can be made of thermoplastic material; specifically, such as polycarbonate, polystyrene, polymethyl methacrylate, MMA styrene copolymer, thermoplastic polyurethane, or ethylene vinyl acetate, but not restricted thereby.

In detail, the transparent wires 10 and the opaque wires 11 are alternatively weaved to form the weave unit. Please refer to FIG. 1; one exemplary transparent wire 10 is alternatively weaved with the opaque wires 11. In the embodiment, the opaque wires 11 extend in a longitudinal direction and the transparent wire 10 extends in a latitudinal direction. In other words, the transparent wire(s) 10 and the opaque wire(s) 11 are perpendicularly weaved and the crossing portions of the opaque wire(s) 11 and the transparent wire(s) 10 are defined as the interweave points 101, as shown in FIGS. 1 and 2.

On the other hand, the lighting module 12 is disposed on one side of the transparent wires 10. As shown in FIG. 1A, the lighting module 12 can include at least one light-emitting device 122 and a control device 121 which is applied for controlling the light-emitting device 122. In detail, the transparent wires 10 have a light entrance port 100 on one side thereof, and the light generated by the light-emitting device 122 can be transmitted into the transparent wires 10 through the light entrance port 100.

Please refer to FIG. 1 again; the density of the interweave point 101 on each transparent wire 10 increases in the direction of being away from the lighting module 12, i.e., the density of the interweave point 101 is high when the interweave points 101 near the light-emitting device 122. In the exemplary embodiment, the density of the interweave point 101 on each transparent wire 10 increases gradually. For example, the distance L1 between two adjacent interweave points 101 which are near the light-emitting device 122 is larger than the distance L2 between two adjacent interweave points 101 which are far away from the light-emitting device 122. In other words, the density of the interweave point 101 is changing from a low degree to a high degree in the latitudinal direction. By increasing the density of the interweave point 101, the light generated by the light-emitting device 122 can be transmitted toward the opposite side of the weave unit due to the resistance variation. As a result, the weave unit of the present invention provides uniform illumination. The light transmitted in the transparent wire 10 can be reflected by the interweave points 101 so that the light decay of the transmission distance can be compensated. Therefore, the non-uniform illumination resulted from the light decay of the transmission distance is corrected to provide for the uniform illumination on the weave structure.

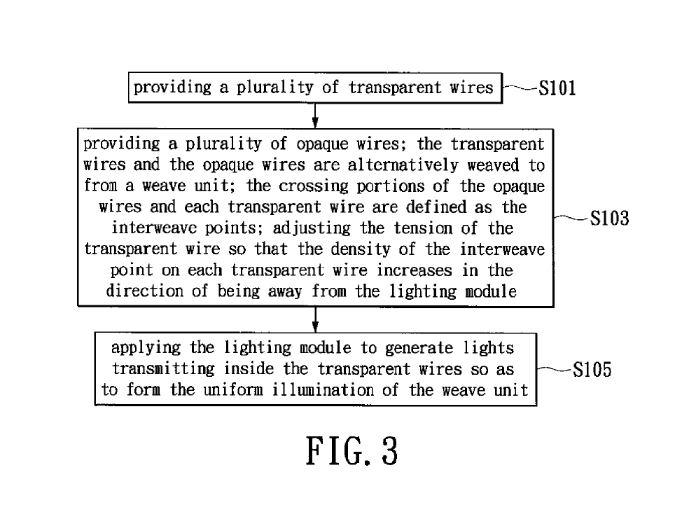

Please refer to FIG. 3; the manufacturing method of the instant disclosure is shown. The method at least has the following steps:

Step S101 is providing a plurality of transparent wires 10. A lighting module 12 is located at one side of the transparent wires 10. In detail, at least one light-emitting device 122 of the lighting module 12 corresponds to the light entrance port 100 of the transparent wires 10.

Step S103 is providing a plurality of opaque wires 11, and the transparent wires 10 and the opaque wires 11 are alternatively weaved to from a weave unit. As mentioned above, the opaque wires 11 extend in a longitudinal direction and the transparent wire 10 extends in a latitudinal direction. In other words, the transparent wire(s) 10 and the opaque wire(s) 11 are perpendicularly weaved and the crossing portions of the opaque wire(s) 11 and the transparent wire(s) 10 are defined as the interweave points 101. Furthermore, in the step of weaving the opaque wire(s) 11 and the transparent wire(s) 10, the tension of the transparent wire(s) 10 is tuned to control the variation of the density of the interweave point 101. In the exemplary embodiment, the tension of the transparent wire(s) 10 is controlled from a loose tension to a tight tension so that the density of the interweave point 101 on each transparent wire 10 increases in the direction of being away from the lighting module 12.

Step S105 is applying the lighting module 12 to generate lights inside the transparent wires 10 so as to form the uniform illumination of the weave unit. In the step, the lights of the light-emitting device 122 of the lighting module 12 transmit into the transparent wires 10 through the light entrance port 100. The lights can transmit in long distance due to the low resistance of the low density of the interweave points 101 so that the light decay can be compensated. On the other hand, the problem of non-uniform illumination can be solved.

To sum up, by controlling the density of the interweave points 101 being from a low degree to a high degree, the interweave points 101 of high density provide for guiding lights forward to compensate the light decay. Furthermore, the low resistance of low interweave point density allows the light to transmit in long distance. Therefore, the light decay can be corrected and compensated to perform the uniform illumination.

The description above only illustrates specific embodiments and examples of the present invention. The present invention should therefore cover various modifications and variations made to the herein-described structure and operations of the present invention, provided they fall within the scope of the present invention as defined in the following appended claims.

What is claimed is:

1. A weave unit with uniform illumination, comprising:
a plurality of opaque wires;
a plurality of transparent wires alternatively weaved with the opaque wires to form a weave structure, wherein a plurality of interweave points is defined on the crossing portions of the opaque wires and the transparent wires;
a lighting module disposed on one side of the transparent wires;
wherein the density of the interweave point on each of the transparent wires increases in the direction of being away from the lighting module; thereby, the light of the lighting module transmits inside the transparent wires for generating uniform illumination.

2. The weave unit as claimed in claim 1, wherein the transparent wires are optical fibers.

3. The weave unit as claimed in claim 1, wherein the lighting module includes at least one light-emitting device and a control device controlling the light-emitting device.

4. The weave unit as claimed in claim 3, wherein the ends of the transparent wires have a light entrance port on one side thereof, and the light of the light-emitting device enters into the transparent wires through the light entrance port.

5. The weave unit as claimed in claim 1, wherein the opaque wires extend in a longitudinal direction, the transparent wires extend in a latitudinal direction, the density of the interweave point on each of the latitudinal transparent wires increases in the latitudinal direction of being away from the lighting module.

6. A manufacturing method of a weave unit with uniform illumination, comprising the following steps:
providing a plurality of transparent wires and a lighting module disposed on one side of the transparent wires;
providing a plurality of opaque wires alternatively weaved with the transparent wires to form a weave structure, wherein a plurality of interweave points is defined on the crossing portions of the opaque wires and the transparent wires, and adjusting the tension of the transparent wires so that the density of the interweave point on each of the transparent wires increases in the direction of being away from the lighting module; and
applying the lighting module to emit light to transmit inside the transparent wires for generating uniform illumination.

7. The manufacturing method as claimed in claim 6, wherein the transparent wires are optical fibers.

8. The manufacturing method as claimed in claim 6, wherein in the step of adjusting the tension of the transparent wires, the tension of the transparent wires is changed from a loose degree to a tight degree in the direction of being away from the lighting module.

9. The manufacturing method as claimed in claim 6, wherein the lighting module includes at least one light-emitting device and a control device controlling the light-emitting device.

10. The manufacturing method as claimed in claim 9, wherein the ends of the transparent wires have a light entrance port on ends thereof, and the light of the light-emitting device enters into the transparent wires through the light entrance port in the step of applying the lighting module.
